(19) United States
(12) Patent Application Publication
(10) Pub. No.: US 2024/0025001 A1
(43) Pub. Date: Jan. 25, 2024

(54) WORKPIECE GRINDING METHOD

(71) Applicant: DISCO CORPORATION, Tokyo (JP)

(72) Inventors: Yu IIJIMA, Tokyo (JP); Fumiaki ITO, Tokyo (JP); Taesup YOO, Tokyo (JP)

(21) Appl. No.: 18/350,164

(22) Filed: Jul. 11, 2023

(30) Foreign Application Priority Data
Jul. 19, 2022 (JP) 2022-114833

(51) Int. Cl. B24B 7/02; B24B 41/06

(52) U.S. Cl. CPC B24B 7/02; B24B 41/06

(57) ABSTRACT

Prior to a stopping step in which spark-out is conducted, a spacing step of operating a moving mechanism to space a chuck table and a grinding wheel from each other while maintaining a state in which a plurality of grindstones and a workpiece are in contact with each other is carried out. In the spacing step, a grinding load is reduced. Thus, as compared to the case where the spacing step is not conducted, the length of time necessary for completing the spark-out is shortened, and the length of time necessary for grinding the workpiece can be restrained from being prolonged.

### BACKGROUND OF THE INVENTION

### Field of the Invention

The present invention relates to a workpiece grinding method for grinding a workpiece.

### Description of the Related Art

Chips of such devices as integrated circuits (ICs) are indispensable constituent elements of various electronic apparatuses such as mobile phones and personal computers. Such chips are manufactured, for example, by thinning a workpiece such as a wafer formed on its front surface with a number of devices and thereafter dividing the workpiece by each of regions including the individual devices.

As a method for thinning the workpiece, there may be mentioned, for example, grinding of the back surface side of the workpiece by a grinding apparatus. The grinding apparatus typically includes a chuck table rotatable with a straight line passing through the center of a holding surface as a rotational axis and a spindle which has a tip part to which an annular grinding wheel having a plurality of grindstones arranged thereon in the state of being dispersed in an annular pattern is mounted.

In the grinding apparatus, the workpiece is ground by bringing the workpiece and the grinding wheel into contact with each other by a moving mechanism capable of adjusting the spacing between the chuck table and the grinding wheel, while rotating both the chuck table holding the workpiece on a holding surface and the spindle. In other words, this grinding is carried out in a state in which both the chuck table and the grinding wheel press each other through the workpiece in a state in which both of them are being rotated.

When the workpiece is thus ground, periodic ruggedness (kerfs) may be formed on the ground surface of the workpiece. Hence, in grinding the workpiece, what is generally called spark-out, that is, grinding for removing the kerfs and flattening the ground surface of the workpiece, may be conducted at the end (see, for example, Japanese Patent Laid-open No. 2003-236736 and Japanese Patent Laid-open No. 2009-12134).

Specifically, the spark-out is conducted by stopping the operation of the moving mechanism in a state in which the workpiece and the plurality of grindstones are in contact with each other while rotating both the chuck table holding the workpiece on the holding surface and the spindle.

During the spark-out, there occurs what is generally called spring-back in which the spacing between the chuck table and the grinding wheel is reduced while a load (grinding load) exerted on both of them is reduced by mutual pressing between the chuck table and the grinding wheel through the workpiece. When spring-back occurs, the workpiece is ground, and when the spring-back is substantially ended, the workpiece is no longer ground.

### SUMMARY OF THE INVENTION

In order to grind a workpiece formed from a hard material such as silicon carbide (SiC), gallium nitride (GaN), or sapphire (Al₂O₃), it may be necessary to increase the grinding load. It is to be noted, however, that, in the case where the grinding load is great, the length of time necessary for completing the spark-out is also prolonged.

Hence, in this case, the throughput of grinding of the workpiece by the grinding apparatus may be lowered. In consideration of this point, it is an object of the present invention to provide a workpiece grinding method by which the length of time necessary for grinding a workpiece can be restrained from being prolonged.

In accordance with an aspect of the present invention, there is provided a workpiece grinding method for grinding a workpiece by a grinding apparatus including a chuck table rotatable with a straight line passing through a center of a holding surface as a rotational axis, a spindle that has a tip part to which an annular grinding wheel having a plurality of grindstones arranged thereon in a state of being dispersed in an annular pattern is mounted, and a moving mechanism capable of adjusting a spacing between the chuck table and the grinding wheel, the workpiece grinding method including a holding step of holding the workpiece on the holding surface of the chuck table, and a grinding step of operating the moving mechanism such that the plurality of grindstones and the workpiece are brought into contact with each other while rotating both the chuck table and the spindle, to thereby grind the workpiece, after the holding step. The grinding step includes an approaching step of operating the moving mechanism to cause the chuck table and the grinding wheel to approach each other such that the workpiece is ground in a state in which the chuck table and the grinding wheel press each other through the workpiece, a spacing step of operating the moving mechanism to space the chuck table and the grinding wheel from each other in such a manner as to reduce a grinding load exerted on the chuck table and the grinding wheel, while maintaining the state in which the plurality of grindstones and the workpiece are in contact with each other, after the approaching step, and a stopping step of stopping the operation of the moving mechanism such that the workpiece is ground while the grinding load is reduced, after the spacing step.

In the present invention, prior to the stopping step in which the spark-out is conducted, the spacing step of operating the moving mechanism to space the chuck table and the grinding wheel from each other while maintaining the state in which the plurality of grindstones and the workpiece are in contact with each other is carried out.

In the spacing step, the grinding load exerted on the chuck table and the grinding wheel is reduced. In the present invention, therefore, the length of time necessary for completing the spark-out is shortened as compared to the case where the spacing step is not conducted, and it is possible to restrain the length of time necessary for grinding the workpiece from being prolonged.

The above and other objects, features and advantages of the present invention and the manner of realizing them will become more apparent, and the invention itself will best be understood from a study of the following description and an appended claim with reference to the attached drawings showing a preferred embodiment of the invention.

### BRIEF DESCRIPTION OF THE DRAWINGS

FIG. 1 is a perspective view schematically depicting an example of a grinding apparatus;

FIG. 2 is a partly sectional side view schematically depicting an example of the grinding apparatus;

FIG. 3 is a flow chart schematically depicting an example of a workpiece grinding method for grinding a workpiece by the grinding apparatus;

FIG. 4 is a flow chart schematically depicting an example of an operation at the time of grinding the workpiece; and

FIG. 5 is a graph schematically depicting time variation of a grinding load exerted on a chuck table and a grinding wheel through the workpiece at the time of grinding the workpiece.

### DETAILED DESCRIPTION OF THE PREFERRED EMBODIMENT

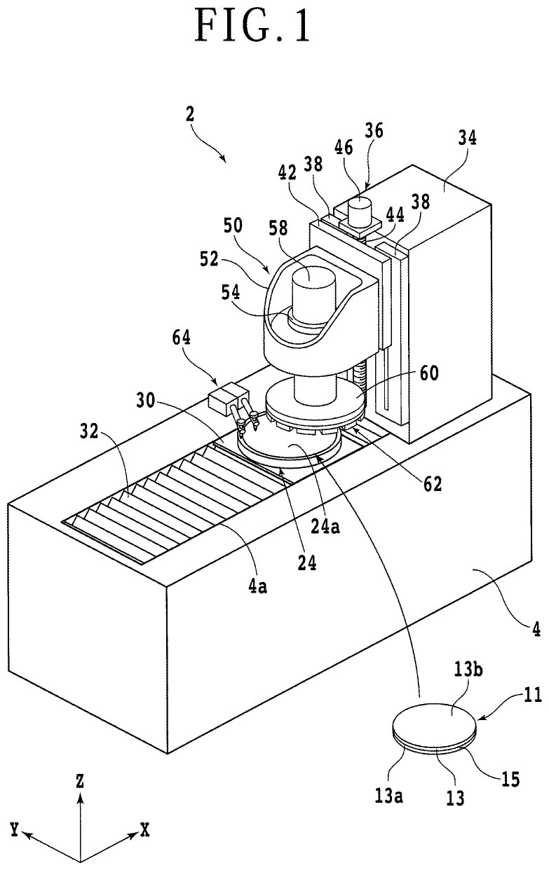

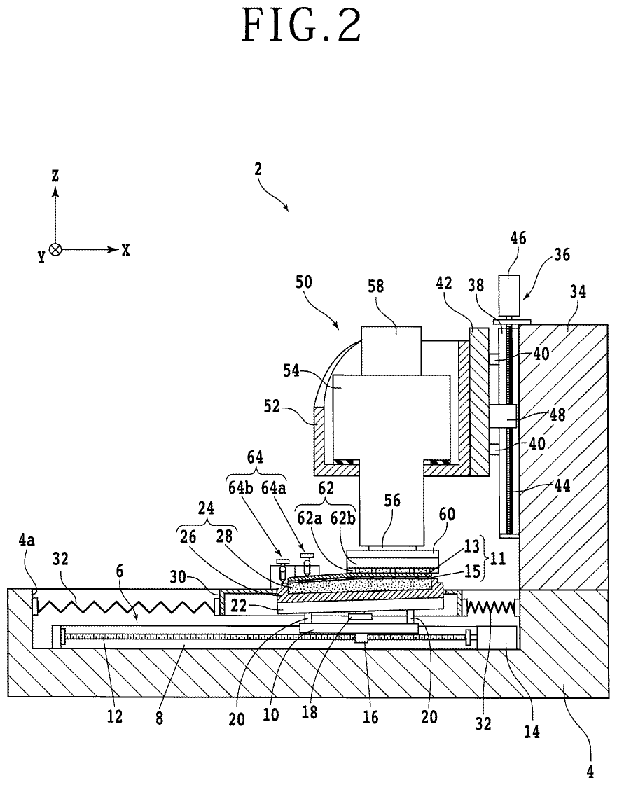

An embodiment of the present invention will be described with reference to the attached drawings. FIG. 1 is a perspective view schematically depicting an example of a grinding apparatus, and FIG. 2 is a partly sectional side view schematically depicting an example of the grinding apparatus depicted in FIG. 1.

Note that an X-axis direction (front-rear direction) and a Y-axis direction (left-right direction) depicted in FIGS. 1 and 2 are mutually orthogonal directions on a horizontal plane, and a Z-axis direction (upper-lower direction) is a direction (vertical direction) orthogonal to the X-axis direction and the Y-axis direction.

The grinding apparatus denoted by 2 and depicted in FIGS. 1 and 2 has a base 4 that supports each of constituent elements. An upper surface of the base 4 is formed with a rectangular parallelepiped groove 4a extending along the X-axis direction. On a bottom surface of the groove 4a, an X-axis direction moving mechanism 6 for moving a chuck table 24 described later along the X-axis direction is provided.

The X-axis direction moving mechanism 6 has a pair of guide rails 8 respectively extending along the X-axis direction. On an upper side of the pair of guide rails 8, a rectangular parallelepiped X-axis moving plate 10 is attached in the manner of being slidable along the X-axis direction. In addition, between the pair of guide rails 8, a screw shaft 12 extending along the X-axis direction is disposed.

To a rear end part of the screw shaft 12, a pulse motor 14 for rotating the screw shaft 12 is connected. In addition, on a circumferential surface formed with a screw thread of the screw shaft 12, a nut 16 for accommodating a number of balls that circulate according to the rotation of the screw shaft 12 is provided, to constitute a ball screw.

Besides, the nut 16 is fixed to a lower surface side of the X-axis moving plate 10. Thus, when the screw shaft 12 is rotated by the pulse motor 14, the X-axis moving plate 10 is moved along the X-axis direction together with the nut 16.

On the X-axis moving plate 10, there are provided a rotary body with a driven pulley 18 connected to a lower end part thereof and a rotational drive source (not illustrated) such as a motor connected to a driving pulley (not illustrated). In addition, an endless belt (not illustrated) is wrapped around the driven pulley 18 and the driving pulley.

Further, an inclination adjusting mechanism having one fixed shaft (not illustrated) and two movable shafts 20 the lengths of which along the Z-axis direction are variable is provided on the X-axis moving plate 10. Besides, the fixed shaft and the two movable shafts 20 are connected to a lower surface side of a table base 22, and support the table base 22.

A through-hole (not illustrated) is formed in the center of the table base 22, and the rotary body with the driven pulley 18 connected to the lower end part thereof is passed through the through-hole. An upper end part of the rotary body is connected to a lower surface side of the circular plate-shaped chuck table 24.

Hence, when the rotational drive source connected to the driving pulley is operated in such a manner as to rotate the endless belt wrapped around the driven pulley 18, the chuck table 24 is rotated along the circumferential direction of the chuck table 24.

In addition, the chuck table 24 is supported on the table base 22 through a bearing (not illustrated). Thus, even when the chuck table 24 is rotated as described above, the table base 22 is not rotated.

On the other hand, when the inclination adjusting mechanism provided on the X-axis moving plate 10 is operated, that is, when the length of at least one of the two movable shaft 20 along the Z-axis direction is adjusted, not only the inclination of the table base 22 but also the inclination of the chuck table 24 is adjusted.

The chuck table 24 has a circular plate-shaped frame body 26 formed of ceramic or the like. The frame body 26 has a circular plate-shaped bottom wall and a cylindrical side wall erected from the bottom wall. In other words, a circular plate-shaped recess defined by the bottom wall and the side wall is formed on an upper surface side of the frame body 26.

Note that the inside diameter of the side wall of the frame body 26 is slightly shorter than the diameter of a workpiece 11 to be described later, and the outside diameter thereof is slightly longer than the diameter of the workpiece 11. In addition, the bottom wall of the frame body 26 is formed with a flow channel (not illustrated) that opens at a bottom surface of the recess, and the flow channel communicates with a suction source (not illustrated) such as an ejector.

Further, a circular plate-shaped porous plate 28 having a diameter substantially equal to the diameter of the recess is fixed to the recess formed on the upper surface side of the frame body 26. The porous plate 28 is formed of, for example, porous ceramic. Besides, an upper surface of the porous plate 28 and an upper surface of the side wall of the frame body 26 have a shape corresponding to a side surface of a cone (a shape in which a center is projected more than a periphery).

When the suction source communicating with the flow channel formed inside the frame body 26 is operated, a suction force acts on a space in the vicinity of an upper surface of the porous plate 28. Thus, the upper surface of the porous plate 28 and the upper surface of the side wall of the frame body 26 function as a holding surface 24a of the chuck table 24 (see FIG. 1).

For example, by operating the suction source in a state in which the workpiece 11 is placed on the holding surface 24a of the chuck table 24, the workpiece 11 is held by the chuck table 24. The workpiece 11 has a wafer 13 which is formed of, for example, silicon carbide, gallium arsenide, sapphire, or the like, and which is formed on its front surface 13a with a plurality of devices.

In addition, a protective tape 15 which is formed of, for example, resin and which prevents damaging of the devices when the back surface 13b side of the wafer 13 is ground is adhered to the front surface 13a of the wafer 13. The workpiece 11 is held by the chuck table 24 such that the wafer 13 is held through the protective tape 15, in other words, such that the back surface 13b of the wafer 13 is exposed.

Further, in the periphery of the chuck table 24, there is provided a rectangular parallelepiped table cover 30 that surrounds the chuck table 24 such that the holding surface 24a is exposed. The width (length along the Y-axis direction) of the table cover 30 is substantially equal to the width of the groove 4a formed in the upper surface of the base 4.

In addition, on the front and rear sides of the table cover 30, there are provided dustproof droplet-proof covers 32 capable of contracting and extending along the X-axis direction. Besides, a tetragonal prismatic support structure 34 is provided in that region of the upper surface of the base 4 which is located on the rear side of the groove 4a.

On a front surface of the support structure 34, there is provided a Z-axis direction moving mechanism 36 capable of adjusting the spacing between the chuck table 24 and a grinding wheel 62 to be described later. The Z-axis direction moving mechanism 36 has a pair of guide rails 38 respectively extending along the Z-axis direction.

On the front side of the respective ones of the pair of guide rails 38, there is provided a slider 40 in the state of being slidable along the Z-axis direction (see FIG. 2). In addition, a front end part of the slider 40 is fixed to a rear surface side of a rectangular parallelepiped Z-axis moving plate 42. Further, between the pair of guide rails 38, there is disposed a screw shaft 44 extending along the Z-axis direction.

To an upper end part of the screw shaft 44, a pulse motor 46 for rotating the screw shaft 44 is connected. In addition, on a circumferential surface formed with the screw thread of the screw shaft 44, a nut 48 that accommodates a number of balls that circulate according to the rotation of the screw shaft 44 is provided, to constitute a ball screw.

Besides, the nut 48 is fixed to the rear surface side of the Z-axis moving plate 42. Hence, when the screw shaft 44 is rotated by the pulse motor 46, the Z-axis moving plate 42 is moved along the Z-axis direction together with the nut 48.

On the front side of the Z-axis moving plate 42, a grinding unit 50 is provided. The grinding unit 50 has a cylindrical holding member 52 fixed to the front surface of the Z-axis moving plate 42. Inside the holding member 52, a cylindrical spindle housing 54 extending along the Z-axis direction is provided.

Inside the spindle housing 54, a cylindrical spindle 56 extending along the Z-axis direction is provided (see FIG. 2). The spindle 56 is supported by the spindle housing 54 in a rotatable manner, and an upper end part (base end part) thereof is connected to a rotational drive source 58 such as a motor.

In addition, a lower end part (tip part) of the spindle 56 is exposed from the spindle housing 54, forming a circular plate-shaped wheel mount 60. To a lower surface side of the wheel mount 60, the annular grinding wheel 62 having an outside diameter substantially equal to the diameter of the wheel mount 60 is mounted with use of fixing members (not illustrated) such as bolts.

The grinding wheel 62 includes a plurality of grindstones 62a and a wheel base 62b having a lower surface on which the plurality of grindstones 62a are disposed in the state of being dispersed in an annular pattern. When the rotational drive source 58 is operated, the wheel mount 60 and the grinding wheel 62 are rotated together with the spindle 56, with a straight line along the Z-axis direction as a rotational axis.

Note that the plurality of grindstones 62a have abrasive grains of diamond, cBN, or the like dispersed in a bond material such as a vitrified bond or a resin bond. Besides, the wheel base 62b is formed from a metallic material such as stainless steel or aluminum.

Further, in the vicinity of the grinding wheel 62, a grinding water supply nozzle is provided. The grinding water supply nozzle supplies, at a predetermined flow rate, liquid (grinding water) such as pure water to a processing point when the workpiece 11 is ground by the plurality of grindstones 62a.

In addition, in a region located on a lateral side of the groove 4a in the upper surface of the base 4 and in the vicinity of the grinding unit 50, a measuring unit 64 is provided. The measuring unit 64 has, for example, a pair of height gauges 64a and 64b for measuring the heights of the positions where respective probes make contact.

The probe of the height gauge 64a is, for example, disposed in such a manner as to make contact with the back surface 13b of the wafer 13 included in the workpiece 11 held by the chuck table 24. Besides, the probe of the height gauge 64b is disposed, for example, in such a manner as to make contact with the holding surface 24a of the chuck table 24 (specifically, the upper surface of the side wall of the frame body 26).

By thus disposing the probes of the height gauges 64a and 64b prior to or during grinding of the back surface 13b side of the wafer 13, the thickness of the workpiece 11 can be measured by the measuring unit 64.

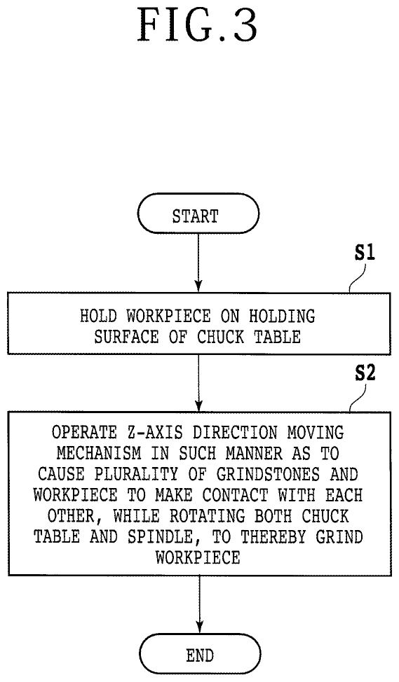

FIG. 3 is a flow chart schematically depicting an example of the workpiece grinding method for grinding the workpiece 11 in the grinding apparatus 2. In this method, first, the workpiece 11 is held on the holding surface 24a of the chuck table 24 (holding step: S1).

Specifically, the workpiece 11 is conveyed in onto the chuck table 24 such that the protective tape 15 is located on the lower side and that the center of the lower surface of the workpiece 11 (the lower surface of the protective tape 15) coincides with the center of the holding surface 24a of the chuck table 24. Then, the suction source communicating with the flow channel formed in the bottom wall of the frame body 26 of the chuck table 24 is operated, whereby a suction force is made to act on the workpiece 11.

As a result, the workpiece 11 is elastically deformed following the holding surface 24a of the chuck table 24. In other words, the workpiece 11 is deformed in such a manner as to correspond to a side surface of a cone, and the holding surface 24a of the chuck table 24 is covered with the workpiece 11. As a result, the workpiece 11 is held by the holding surface 24a of the chuck table 24.

After this holding step (S1), while both the chuck table 24 and the spindle 56 are being rotated, the Z-axis direction moving mechanism 36 is operated such that the plurality of grindstones 62a and the workpiece 11 make contact with each other, to thereby grind the workpiece 11 (grinding step: S2).

In this grinding step (S2), first, the X-axis direction moving mechanism 6 (specifically, the pulse motor 14) is operated to adjust the position of the chuck table 24 such that the trajectory of the plurality of grindstones 62a at the time of rotation of the spindle 56 overlaps with the workpiece 11 in the Z-axis direction.

Note that, in this adjustment, for example, part of a line segment which connects the center and the periphery of the holding surface 24a of the chuck table 24 by the shortest distance and which is orthogonal to the Z-axis direction and the trajectory of the plurality of grindstones 62a in a rotating state overlap with each other in the Z-axis direction.

In other words, the coordinates of part of the line segment in a coordinate plane (XY coordinate plane) orthogonal to the Z-axis direction and the coordinates of the trajectory are made to overlap with each other in the Z-axis direction. Hence, if necessary, prior to this adjustment, the inclination of the chuck table 24 may be adjusted by operation of the inclination adjusting mechanism.

Next, the probe of the height gauge 64a is disposed to make contact with the upper surface of the workpiece 11 (the back surface 13b of the wafer 13), and the probe of the height gauge 64b is disposed to make contact with the upper surface of the side wall of the frame body 26 of the chuck table 24.

In this instance, in the measuring unit 64, the thickness of the workpiece 11 at the time point of starting the grinding step (S2) is measured. Further, the measurement of the thickness of the workpiece 11 by the measuring unit 64 is continuously carried out during the grinding step (S2).

Next, while both the chuck table 24 and the spindle 56 are rotated, the Z-axis direction moving mechanism 36 (specifically, the pulse motor 14) is operated to make the chuck table 24 and the grinding wheel 62 approach each other, that is, to lower the grinding wheel 62, such that the upper surface of the workpiece 11 and the lower surfaces of the plurality of grindstones 62a make contact with each other.

Note that when the lower surfaces of the plurality of grindstones 62a and the upper surface of the workpiece 11 make contact with each other, a current supplied to the rotational drive source 58 for rotating the spindle 56 becomes large, and a grinding load exerted on the chuck table 24 and the grinding wheel 62 also becomes large. Hence, detecting the current or the grinding load makes it possible to identify the timing of contact between the lower surfaces of the plurality of grindstones 62a and the upper surface of the workpiece 11.

In addition, the contact interface between the lower surfaces of the plurality of grindstones 62a and the upper surface of the workpiece 11 is supplied with grinding water from the grinding water supply nozzle provided in the vicinity of the grinding wheel 62. When the lower surfaces of the plurality of grindstones 62a and the upper surface of the workpiece 11 make contact with each other, grinding of the workpiece 11 is started.

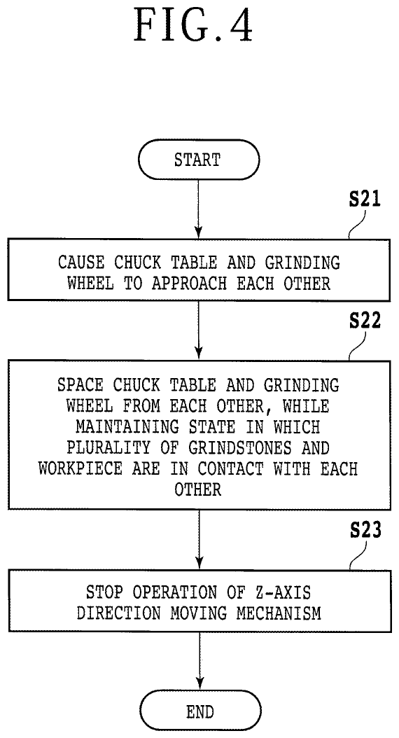

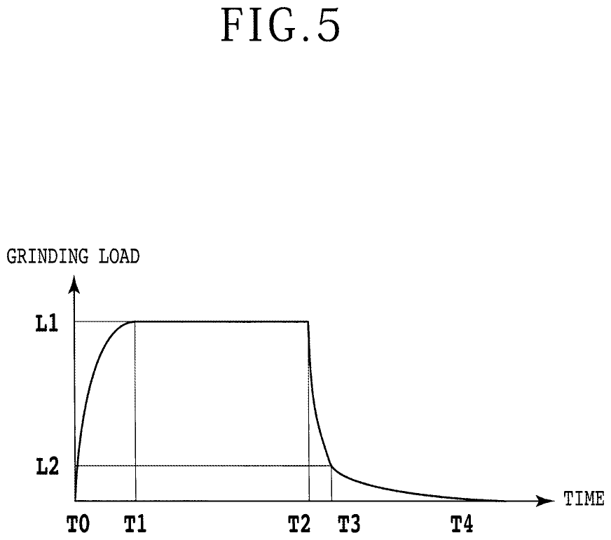

FIG. 4 is a flow chart schematically depicting an example of an operation at the time of grinding the workpiece 11. Besides, FIG. 5 is a graph schematically depicting time variation of the grinding load exerted on the chuck table 24 and the grinding wheel 62 through the workpiece 11 when the workpiece 11 is ground.

At the time of grinding the workpiece 11, first, the chuck table 24 and the grinding wheel 62 are made to approach each other (approaching step: S21). Specifically, the Z-axis direction moving mechanism 36 is operated in such a manner as to lower the grinding wheel 62 at a predetermined grinding feed speed (for example, 0.1 to 0.5 μm/s, typically 0.3 μm/s).

Here, in the initial period (T0 to T1 depicted in FIG. 5) of the approaching step (S21), the grinding feed speed becomes greater than the reducing speed of the thickness of the workpiece 11 removed by grinding. In this case, the grinding load also becomes large. On the other hand, as the grinding load becomes greater, the reducing speed also becomes greater.

Further, when the grinding load reaches L1 which is the grinding load at the time when the reducing speed becomes equal to the grinding feed speed, the grinding load no longer varies from L1. In addition, the approaching step (S21) ends, for example, at the timing (T2 depicted in FIG. 5) when the thickness of the workpiece 11 measured by the measuring unit 64 reaches a predetermined thickness.

After the approaching step (S21), while a state in which the plurality of grindstones 62a and the workpiece 11 are in contact with each other is maintained, the chuck table 24 and the grinding wheel 62 are spaced from each other (spacing step: S22).

Specifically, the Z-axis direction moving mechanism 36 is operated in such a manner as to slightly raise the grinding wheel 62 at a predetermined retracting speed (for example, 0.5 to 1.5 μm/s, typically 1.0 μm/s), in a range in which the workpiece 11 rises following up to the plurality of grindstones 62a by spring-back.

Here, in the spacing step (S22), the grinding load is reduced with time. Further, the spacing step (S22) ends, for example, at the timing (T3 depicted in FIG. 5) when the grinding load is reduced to L2 which is less than ⅓ times of L1.

After the spacing step (S22), the operation of the Z-axis direction moving mechanism 36 is stopped (stopping step: S23). As a result, spark-out in which the workpiece 11 is ground while the grinding load is reduced is conducted.

Further, the stopping step (S23) ends, for example, at the timing when the grinding load has been reduced to below ⅕ times of L2 or at the timing (T4 depicted in FIG. 5) when a predetermined period of time has elapsed. By the above-described steps, grinding of the workpiece 11 by the grinding apparatus 2 is completed.

When the grinding of the workpiece 11 has been completed, the rotation of both the chuck table 24 and the spindle 56 and the supply of grinding water from the grinding water supply nozzle are stopped, and the Z-axis direction moving mechanism 36 is operated to space the chuck table 24 and the grinding wheel 62 from each other, that is, to raise the grinding wheel 62.

Subsequently, the probe of the height gauge 64a is moved from the upper surface of the workpiece 11, and the operation of the suction source communicating with the flow channel formed in the bottom wall of the frame body 26 of the chuck table 24 is stopped. Then, the ground workpiece 11 is conveyed out from the chuck table 24.

In the workpiece grinding method as described above, prior to the stopping step (S23) in which the spark-out is conducted, the spacing step (S22) in which the Z-axis direction moving mechanism 36 is operated to space the chuck table 24 and the grinding wheel 62 from each other, while the state of contact between the plurality of grindstones 62a and the workpiece 11 is maintained, is carried out.

In the spacing step (S22), the grinding load exerted on the chuck table 24 and the grinding wheel 62 is reduced. Thus, in this method, the length of time necessary for completing the spark-out is shortened as compared to the case where the spacing step (S22) is not conducted, and it is possible to restrain the length of time necessary for grinding the workpiece 11 from being prolonged.

Note that the contents of the above description are one mode of the present invention, and the present invention is not limited to the contents of the above description. For example, the structure of the grinding apparatus to be used in the present invention is not limited to the structure of the above-described grinding apparatus 2. Specifically, in the grinding apparatus in the present invention, the Z-axis direction moving mechanism for moving the chuck table 24 along the Z-axis direction and the X-axis direction moving mechanism for moving the grinding unit 50 along the X-axis direction may be provided.

Other than those described above, the structures, methods, and the like concerning the above-described embodiment can be modified as required in carrying out the present invention insofar as the modifications do not depart from the scope of the object of the invention.

The present invention is not limited to the details of the above described preferred embodiment. The scope of the invention is defined by the appended claim and all changes and modifications as fall within the equivalence of the scope of the claim are therefore to be embraced by the invention.

What is claimed is:

1. A workpiece grinding method for grinding a workpiece by a grinding apparatus including a chuck table rotatable with a straight line passing through a center of a holding surface as a rotational axis, a spindle that has a tip part to which an annular grinding wheel having a plurality of grindstones arranged thereon in a state of being dispersed in an annular pattern is mounted, and a moving mechanism capable of adjusting a spacing between the chuck table and the grinding wheel, the workpiece grinding method comprising:
a holding step of holding the workpiece on the holding surface of the chuck table; and
a grinding step of operating the moving mechanism such that the plurality of grindstones and the workpiece are brought into contact with each other while rotating both the chuck table and the spindle, to thereby grind the workpiece, after the holding step,
wherein the grinding step includes
an approaching step of operating the moving mechanism to cause the chuck table and the grinding wheel to approach each other such that the workpiece is ground in a state in which the chuck table and the grinding wheel press each other through the workpiece,
a spacing step of operating the moving mechanism to space the chuck table and the grinding wheel from each other in such a manner as to reduce a grinding load exerted on the chuck table and the grinding wheel, while maintaining the state in which the plurality of grindstones and the workpiece are in contact with each other, after the approaching step, and
a stopping step of stopping the operation of the moving mechanism such that the workpiece is ground while the grinding load is reduced, after the spacing step.
